(19) United States
(12) Patent Application Publication
(10) Pub. No.: US 2013/0032893 A1
(43) Pub. Date: Feb. 7, 2013

(54) SEMICONDUCTOR DEVICE COMPRISING METAL GATE ELECTRODE STRUCTURES AND NON-FETS WITH DIFFERENT HEIGHT BY EARLY ADAPTATION OF GATE STACK TOPOGRAPHY

(71) Applicants: Rohit Pal, Dresden (DE); George Mulfinger, Saratoga Springs, NY (US)

(72) Inventors: Rohit Pal, Dresden (DE); George Mulfinger, Saratoga Springs, NY (US)

(73) Assignee: GLOBALFOUNDRIES INC., Grand Cayman (KY)

(21) Appl. No.: 13/550,693

(22) Filed: Jul. 17, 2012

(30) Foreign Application Priority Data
Aug. 4, 2011 (DE) 10 2011 080 439.0

(51) Int. Cl. H01L 27/088; H01L 21/283

(52) U.S. Cl. 257/379; 257/368; 438/585; 257/E27.06; 257/E21.19

(57) ABSTRACT

Gate height scaling in sophisticated semiconductor devices may be implemented without requiring a redesign of non-transistor devices. To this end, the semiconductor electrode material may be adapted in its thickness above active regions and isolation regions that receive the non-transistor devices. Thereafter, the actual patterning of the adapted gate layer stack may be performed so as to obtain gate electrode structures of a desired height for improving, in particular, AC performance without requiring a redesign of the non-transistor devices.

### BACKGROUND OF THE INVENTION

1. Field of the Invention

The present disclosure generally relates to the field of fabricating integrated circuits, and, more particularly, to complex integrated circuits that comprise non-FETs and FETs with metal gate electrode structures of superior AC performance.

2. Description of the Related Art

In modern integrated circuits, a huge number of individual circuit elements, such as field effect transistors, are formed on a single chip area. Typically, feature sizes of these circuit elements are reduced with the introduction of every new circuit generation, to provide currently available integrated circuits with high performance in terms of speed and/or power consumption. A reduction in size of transistors is an important aspect in steadily improving device performance of complex integrated circuits, such as CPUs. The reduction in size commonly brings about an increased switching speed, thereby enhancing signal processing performance.

Due to the decreased dimensions of circuit elements, not only the performance of the individual transistor elements may be improved, but also their packing density may be significantly increased, thereby providing the potential for incorporating increased functionality into a given chip area. For this reason, highly complex circuits have been developed which may include different types of circuits, such as analog circuits, digital circuits and the like, thereby providing entire systems on a single chip (SOC).

Although transistor elements are the dominant circuit element in highly complex integrated circuits and substantially determine the overall performance of these devices, passive components, such as the resistors, electronic fuses or e-fuses, may also strongly influence the overall device performance, wherein the size of these passive circuit elements may also have to be adjusted with respect to the scaling of the transistor elements in order to not unduly consume valuable chip area. Moreover, the passive circuit elements, such as the resistors, may have to be provided with a high degree of accuracy in order to meet tightly set margins according to the basic circuit design. For example, even in substantially digital circuit designs, corresponding resistance values may have to be provided within tightly set tolerance ranges so as to not unduly contribute to operational instabilities and/or increased signal propagation delay. For example, in sophisticated applications, resistors may frequently be provided in the form of “integrated polysilicon” resistors which may be formed above isolation structures so as to obtain the desired resistance value without significantly contributing to parasitic capacitance, as may be the case in “buried” resistive structures which may be formed within the active semiconductor layer. A typical polysilicon resistor may thus require the deposition of the basic polysilicon material, which may frequently be combined with the deposition of a polysilicon gate electrode material for the transistor elements. During the patterning of the gate electrode structures, also the resistors may be formed, the size of which may significantly depend on the basic specific resistance value of the polysilicon material and the subsequent type of dopant material and concentration that may be incorporated into the resistors so as to adjust the resistance values. Since typically the resistance value of doped polysilicon material may be a non-linear function of the dopant concentration, typically specific implantation processes are required, independent of any other implantation sequences for adjusting the characteristics of the polysilicon material of the gate electrodes of the transistors.

Moreover, the continuous drive to shrink the feature sizes of complex integrated circuits has resulted in a gate length of field effect transistors of approximately 50 nm and less. A field effect transistor, irrespective of whether an N-channel transistor or a P-channel transistor is considered, typically comprises so-called “PN junctions” that are formed by an interface of highly doped regions, referred to as drain and source regions, with a slightly doped or non-doped region, referred to as a channel region, that is disposed adjacent to the highly doped regions. In a field effect transistor, the conductivity of the channel region, i.e., the drive current of the conductive channel, is controlled by a gate electrode formed adjacent to the channel region and separated therefrom by a thin insulating layer. The conductivity of the channel region, upon forming a conductive channel due to the application of an appropriate control voltage to the gate electrode, depends on, among other things, the dopant concentration of the drain and source regions, the mobility of the charge carriers and, for a given transistor width, the distance between the source region and the drain region, which is also referred to as channel length.

Presently, most complex integrated circuits are based on silicon due to the substantially unlimited availability, the well-understood characteristics of silicon and related materials and processes, and due to the experience gathered during the last 50 years. Therefore, silicon will likely remain the material of choice for future circuit generations. One reason for the important role that silicon plays for the fabrication of semiconductor devices has been the superior characteristics of a silicon/silicon dioxide interface that allows a reliable electrical insulation of different regions from each other. The silicon/silicon dioxide interface is stable at high temperatures and, thus, allows high temperature processes to be performed, as are typically required for anneal processes in order to activate dopants and to cure crystal damage, without sacrificing the electrical characteristics of the interface. Consequently, in field effect transistors, silicon dioxide has been preferably used as a base material for gate insulation layers which separate the gate electrode, frequently comprised of polysilicon, from the silicon channel region.

Upon further device scaling, however, the reduction of channel length may require a corresponding adaptation of the thickness of the silicon dioxide-based gate dielectric in order to substantially avoid a so-called “short channel” behavior, according to which channel width may have a significant influence on the resulting threshold voltage of the transistor. Aggressively scaled transistor devices with a relatively low supply voltage and, thus, a reduced threshold voltage, therefore, suffer from a significant increase of the leakage current caused by the reduced thickness of a silicon dioxide gate dielectric.

For this reason, replacing silicon dioxide as the material for gate insulation layers has been considered, particularly for highly sophisticated applications. Possible alternative materials include such materials that exhibit a significantly higher permittivity, so that a physically greater thickness of a correspondingly formed gate insulation layer provides a capacitive coupling that would be obtained by an extremely thin silicon dioxide layer. It has been suggested to replace silicon dioxide with high permittivity materials such as tantalum oxide, strontium titanium oxide, hafnium oxide, hafnium silicon oxide, zirconium oxide and the like.

Additionally, transistor performance may further be increased by providing an appropriate conductive material for the gate electrode in order to replace the usually used polysilicon material, since polysilicon may suffer from charge carrier depletion at the vicinity of the interface positioned between the gate dielectric material and the polysilicon material, thereby reducing the effective capacitance between the channel region and the gate electrode during transistor operation. Thus, a gate stack has been suggested in which a high-k dielectric material provides enhanced capacitance, while additionally maintaining any leakage currents at an acceptable level. Since the non-polysilicon material, such as titanium nitride and the like, may be formed such that it may be directly in contact with gate dielectric material, the presence of a depletion zone may, thus, be avoided, while, at the same time, a moderately high conductivity is achieved.

As is well known, the threshold voltage of the transistor may depend on the overall transistor configuration, on a complex lateral and vertical dopant profile of the drain and source regions, and the corresponding configuration of the PN junctions, and on the work function of the gate electrode material. Consequently, in addition to providing the desired dopant profiles, the work function of the metal-containing gate electrode material also has to be appropriately adjusted with respect to the conductivity type of the transistor under consideration. For this reason, typically, metal-containing electrode materials may be used for N-channel transistors and P-channel transistors, which may be provided according to well-established manufacturing strategies in an early manufacturing stage.

On the basis of the metal-containing electrode materials, superior performance in terms of conductivity of the gate electrode structures is also accomplished, while, at the same time, other advantageous effects are achieved, such as avoidance of a depletion zone, which is typically encountered in conventional gate electrode structures having a polysilicon/gate dielectric layer interface. On the other hand, the superior conductivity of the metal-containing electrode material may also require certain reconfiguration of non-transistor elements, such as resistors, electronic fuses and the like, since the overall resistance values of these non-transistor devices also significantly depend on the characteristics of the metal-containing electrode materials.

Consequently, the basic configuration of the sophisticated high-k metal gate electrode structures and the electronic bodies of any non-transistor devices are strongly correlated and a significant change, for instance in the gate electrode structures, may require significant redesigns, which may even result in significant redesign of the circuit layout of complex integrated circuits. In an attempt to further increase overall performance of complex integrated circuits, it has been recognized that, in particular, AC performance of sophisticated transistors may be enhanced by taking into consideration the parasitic capacitance between the gate electrode structure and contact elements to be formed so as to connect to the transistor, wherein, however, improvement with respect to the parasitic gate capacitance may require a significant redesign of the complex metal gate electrode structure, as will be described in more detail with reference to FIG. 1.

FIG. 1 schematically illustrates a cross-sectional view of a semiconductor device 100 comprising a substrate 101, such as a silicon substrate and the like, in which is provided a semiconductor layer 102, such as a silicon layer. As is well known, the semiconductor layer 102 is typically divided into a plurality of active regions or semiconductor regions in and above which one or more transistor elements are to be formed. For convenience, a single active region 102a is illustrated in FIG. 1, in and above which a transistor 150 is provided. Moreover, an isolation region 102b is formed in the semiconductor layer 102 and is comprised of any appropriate dielectric material, such as silicon dioxide and the like. In the example shown, the isolation region 102b is to represent an area of the semiconductor device 100 in which a non-transistor device 160b is provided in the form of a resistor, an electronic fuse and the like. It should be appreciated that providing the non-transistor device 160b on and above the isolation region 102b may provide superior performance with respect to parasitic capacitance, programmability when considering an electronic fuse and the like. For example, in electronic fuses, a significant modification of the resistance is to be induced upon programming the electronic fuse, thereby requiring a significant amount of heat generation, wherein positioning the electronic fuse on the isolation region 102b may provide superior conditions due to the significantly reduced thermal conductivity of the insulating material of the region 102b compared to the moderately high conductivity of the semiconductor material in the semiconductor layer 102, in particular when the semiconductor layer 102 and the substrate 101 form a bulk configuration without any intermediate insulating material, as is the case in silicon-on-insulator (SOI) configurations.

As discussed above, when forming the non-transistor device 160b above the isolation region 102b, which may be highly advantageous in bulk architectures and also in SOI architectures in terms of parasitic capacitance, the device 160b and a gate electrode structure 160a of the transistor 150 may have basically a very similar configuration. For example, the gate electrode structure 160a, which is provided in the form of a high-k metal gate electrode structure, comprises a gate dielectric layer 161 which typically comprises a high-k dielectric material, for instance in the form of a dedicated material layer or in the form of a specific compound of high-k components in combination with conventional dielectric components, depending on the overall process and device requirements. Furthermore, a metal-containing electrode material 162, for instance comprising titanium nitride, tantalum nitride and the like, possibly in combination with a specific work function adjusting metal species, is formed above the gate dielectric layer 161. Next, a silicon material 163 as a further electrode material is typically provided, followed by a metal silicide 164, which also results in superior conductivity and reduced contact resistance. Moreover, sidewalls of the materials 161, 162 are typically confined on the basis of an appropriate protective liner 165, such as a silicon nitride material, followed by any appropriate spacer structure 166, which is typically used for adjusting the lateral and vertical dopant profile of drain and source regions 151 formed in the active region 102a. Typically, a metal silicide 152 is also provided in the drain and source regions 151 in order to reduce series resistance and overall contact resistivity of the transistor 150.

As shown, the non-transistor device 160b, which is illustrated in FIG. 1 as a resistive structure, comprises the components 161, 162 and 163 in combination with the metal silicide 164 which, however, may be provided at end portions of the device 160b, while a formation of the metal silicide in other portions of the semiconductor material 163 may have been avoided, for instance by providing a dedicated blocking material 168, for instance in the form of silicon nitride.

Furthermore, a contact level 120 is provided which may comprise a plurality of dielectric materials, such as a first dielectric layer 121, for instance provided in the form of a silicon nitride material, followed by a second dielectric layer 122, such as a silicon dioxide material and the like. The contact level 120 comprises a plurality of contact elements, such as contact elements 123, which connect to the drain and source regions 151, i.e., to the metal silicide regions 152 of the transistor 150. Furthermore, other contact elements 124 are provided, which may connect to the gate electrode structure 160a (not shown) and which also connect to the non-transistor device 160b, i.e., to the corresponding metal silicide areas 164.

The semiconductor device 100 as illustrated in FIG. 1 may be formed on the basis of the following process strategy. The isolation region 102b is formed in the semiconductor layer 102 on the basis of a well-established process strategy including the patterning of the semiconductor layer 102 so as to form trenches therein, which are subsequently filled with one or more appropriate dielectric materials using well-established deposition and anneal techniques. Thereafter any excess material may be removed. Next, a gate layer stack is formed so as to include the materials 161, 162, 163, possibly in combination with additional hard mask materials and the like, and thereafter a patterning sequence including sophisticated lithography and etch techniques is applied so as to commonly pattern the gate electrode structure 160a and the device 160b. It should be appreciated that providing the materials 161, 162 may include the deposition and patterning of various material layers in order to appropriately adjust threshold voltage characteristics, including the adjustment of an appropriate work function, for the various transistor types to be implemented in the device 100. Furthermore, any high temperature anneal processes may have to be implemented in the overall process flow, wherein typically these processes are performed prior to depositing the silicon material 163 on the basis of well-established deposition techniques. After patterning the gate electrode structure 160a and the device 160b from the previously formed gate layer stack, typically the sensitive materials 161 and 162 have to be confined, which is accomplished by forming the protective liner or spacer 165 using sophisticated deposition techniques. Next, appropriate implantation sequences may be applied, for instance for incorporating an appropriate dopant concentration in the material 163 of the device 160b and also to introduce the dopant species for the drain and source regions 151, which is accomplished by using well-established implantation techniques and masking regimes. In this process sequence, the spacer structure 166 is also provided so as to obtain the desired lateral profile of the drain and source regions 151. After any high temperature processes, the metal silicide regions 152, 164 are formed on the basis of well-established silicidation techniques, wherein, if a complete silicidation of an upper portion of the material 163 in the device 160b is not desired, the blocking material 168 may be formed prior to the silicidation process. It should be appreciated that, typically, a metal silicide may be formed in the entire upper portion of the material 163 when the device 160b is provided as an electronic fuse since usually electromigration effects in the metal silicide are taken advantage of in order to provide superior programmability of an electronic fuse.

Consequently, due to the previous manufacturing sequence, the height of the gate electrode structure 160a, indicated by 160h, is very similar or approximately the same as the height of the non-transistor device 160b. Next, the contact level 120 is formed by depositing the materials 121 and 122 and patterning these materials so as to form contact openings which are subsequently filled with an appropriate conductive material. After the removal of any excess material, the contact elements 123 and 124 are provided as electrically isolated components.

Due to the overall reduced lateral dimensions, in particular of sophisticated transistor elements, the gate electrode structure 160a has to be provided with a gate length of, for instance, 50 nm and significantly less in sophisticated devices, thereby also requiring a corresponding reduction in size of the contact elements 123. In particular, in densely packed device areas, such as memory areas and the like, the pitch between neighboring gate electrode structures requires tightly set lateral dimensions of the contact elements 123, wherein the close proximity of the contact elements 123 with respect to the gate electrode structure 160a may give rise to a significant parasitic capacitance, as indicated by 125, thereby particularly deteriorating the AC performance of the transistor 150. Since the parasitic capacitance 125 critically depends on the gate height 160h and since, generally, conductivity of the sophisticated high-k metal gate electrode structures is higher compared to conventional gate electrode structures having a polysilicon/silicon dioxide interface, it has been proposed to reduce the gate height of the gate electrode structure 160a in order to obtain superior AC performance of the transistor 150. In this case, however, significant redesign of the non-transistor device 160b is also required since the height thereof is also modified, caused by the common manufacturing sequence, as described above. Since a significant redesign, however, may be associated with pronounced modifications of the overall layout of the device 160b, it has been proposed to form non-transistor devices in active regions within the semiconductor layer, which, however, may be less than desirable for bulk architectures, in particular in view of electronic fuses, due to the high thermal conductivity of the active regions into the crystalline material of the substrate 101.

In view of the situation described above, the present disclosure relates to manufacturing techniques and semiconductor devices in which a reduced gate height may be used in combination with non-transistor devices, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally relates to manufacturing techniques and semiconductor devices in which gate height scalability is provided without requiring a redesign of non-transistor devices, such as resistors, electronic fuses and the like. To this end, the semiconductor-based electrode material of a gate layer stack may be patterned so as to provide a reduced thickness for gate electrode structures, while the initial layer thickness may be substantially preserved for non-transistor devices. Thereafter, the gate layer stack may be completed and may be formed into gate electrode structures and non-transistor devices on the basis of well-established process techniques.

One illustrative semiconductor device disclosed herein comprises a transistor which comprises a gate electrode structure having a first height. The gate electrode structure comprises a first high-k gate dielectric material, a metal-containing electrode material formed above the first high-k gate dielectric material and a first semiconductor electrode material that is formed above the metal-containing electrode material. The semiconductor device further comprises a non-transistor device formed above an isolation region and comprising a second semiconductor electrode material that is formed above the isolation region. The non-transistor device has a second height that is greater than the first height.

One illustrative method disclosed herein comprises forming a semiconductor electrode material of a gate layer stack above an active region and an isolation region of a semiconductor device. The method further comprises reducing a thickness of the semiconductor electrode material above the active region and preserving an initial thickness of the semiconductor electrode material above at least a portion of the isolation region. Additionally, the method comprises forming a gate electrode structure on the active region from the gate layer stack and forming a non-transistor device from the gate layer stack above the isolation region.

A further illustrative method disclosed herein relates to forming a semiconductor device. The method comprises forming a semiconductor electrode material above a semiconductor region of a transistor and an isolation region of a non-transistor device. The method further comprises masking the semiconductor electrode material above the isolation region and reducing a thickness of the semiconductor material above the semiconductor region by performing an etch process. Moreover, the method comprises forming the non-transistor device and a gate electrode structure of the transistor from the semiconductor electrode material by performing a common process sequence.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a conventional semiconductor device including a high-k metal gate electrode structure of a transistor and a non-transistor device formed above an isolation region, wherein the metal gate electrode structure and the non-transistor device have substantially the same height;

FIGS. 2a-2g schematically illustrate cross-sectional views of a semiconductor device during various manufacturing stages when forming a gate electrode structure and a non-transistor device on the basis of a common process sequence, wherein the gate height is scaled in accordance with overall device requirements while preserving a desired height of the non-transistor device, according to illustrative embodiments; and

FIG. 2h schematically illustrates a cross-sectional view of the semiconductor device according to illustrative embodiments in which the heat resistance of a metal-containing electrode material may be selectively increased above an isolation region that receives the non-transistor device, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally the present disclosure provides manufacturing techniques and semiconductor devices in which gate height scaling may be applied for sophisticated gate electrode structures by adapting the height of a semiconductor-based electrode material in an early manufacturing stage, i.e., prior to actually patterning the gate electrode structure from a gate layer stack, thereby providing a desired increased height for any non-transistor devices, such as resistors, electronic fuses and the like, while enhancing performance of the sophisticated gate electrode structures. Although basically the gate height scaling may be applied to “conventional” gate electrode structures, i.e., to gate electrode structures comprising an interface formed by a polycrystalline semiconductor material, such as silicon, silicon/germanium and the like, and the gate dielectric layer, since also in this case a certain degree of variability of gate height may be compatible with the overall conductivity requirements of such conventional gate electrode structures, in particular embodiments, the gate height scaling may be applied to sophisticated high-k metal gate electrode structures since generally these gate electrode structures have superior conductivity and thus enable more pronounced range of gate height reduction without unduly compromising the overall conductivity of the gate electrode structures. Thus, although in the following detailed description high-k metal gate electrode structures are referred to, it should be appreciated that the present disclosure should not be restricted to high-k metal gate electrode structures unless such restrictions are specifically set forth in the claims and also in specific embodiments previously described and also presented in the following detailed description.

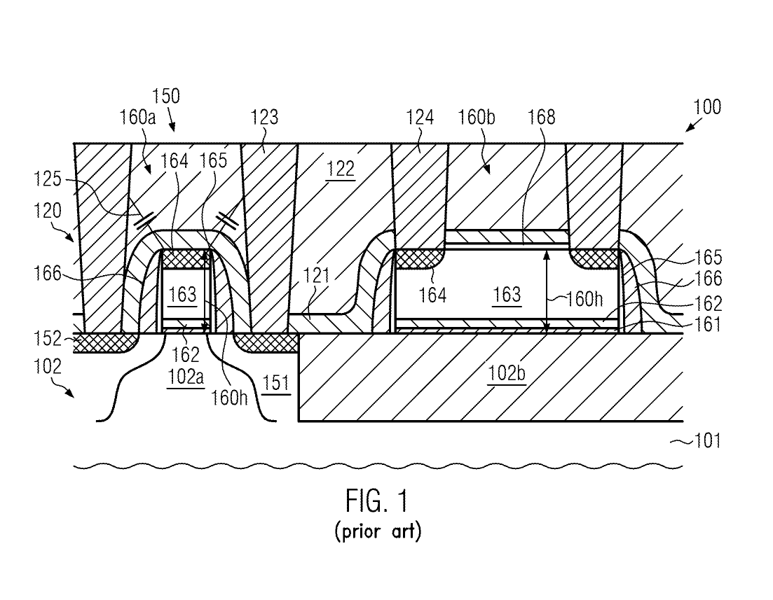

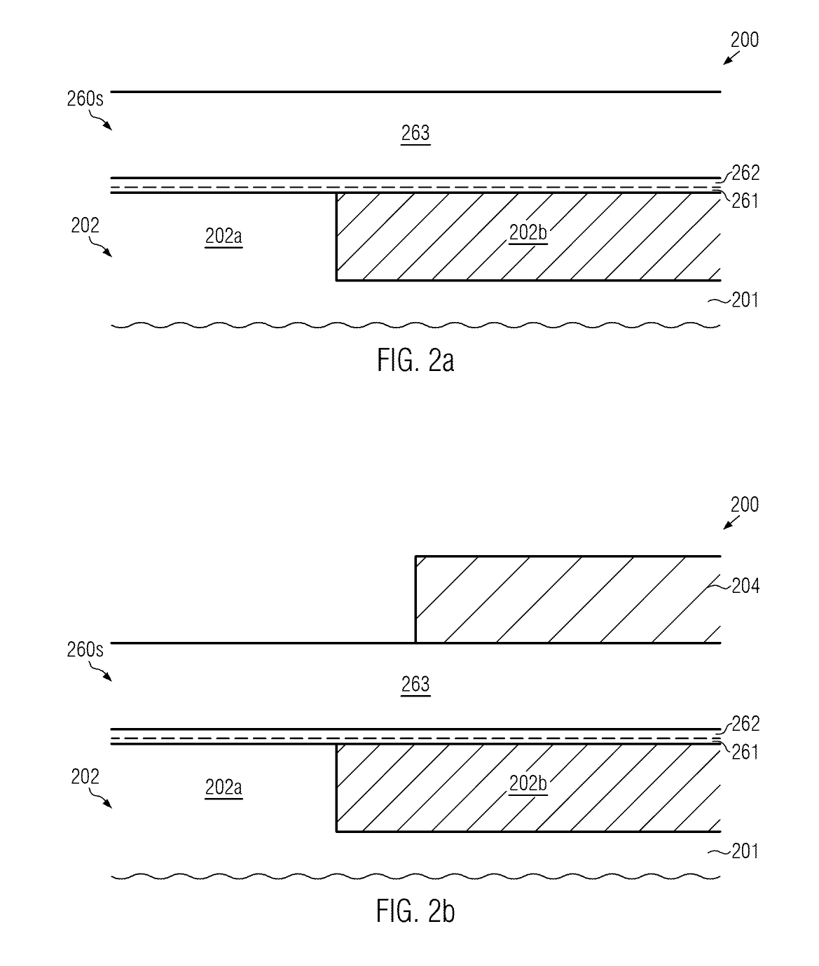

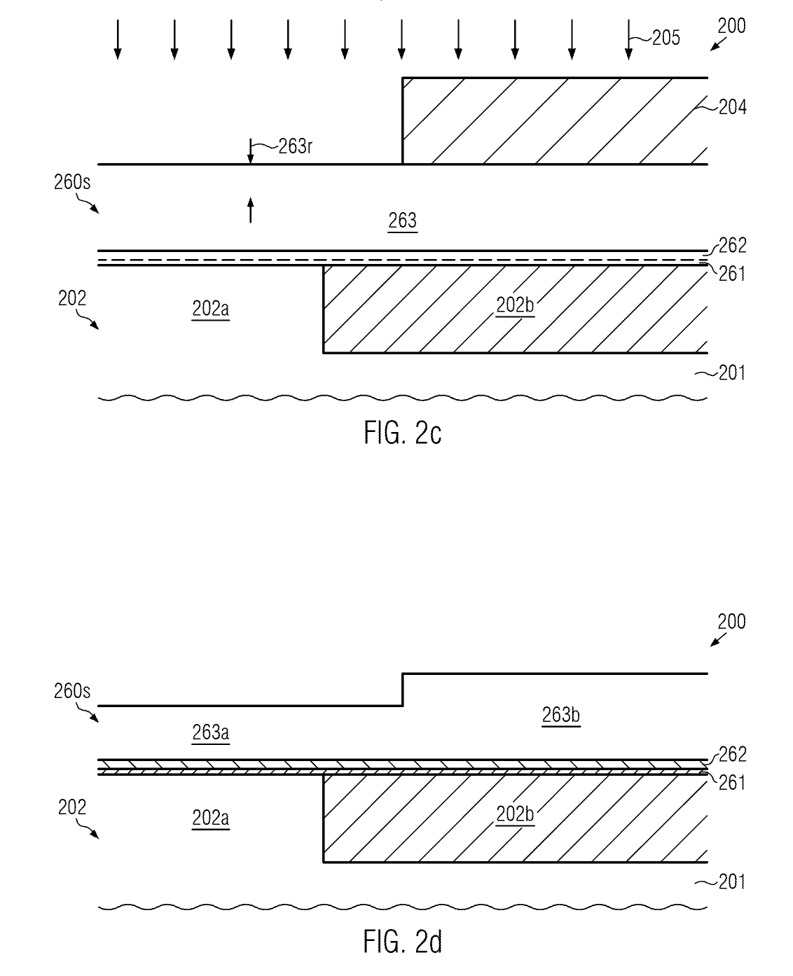

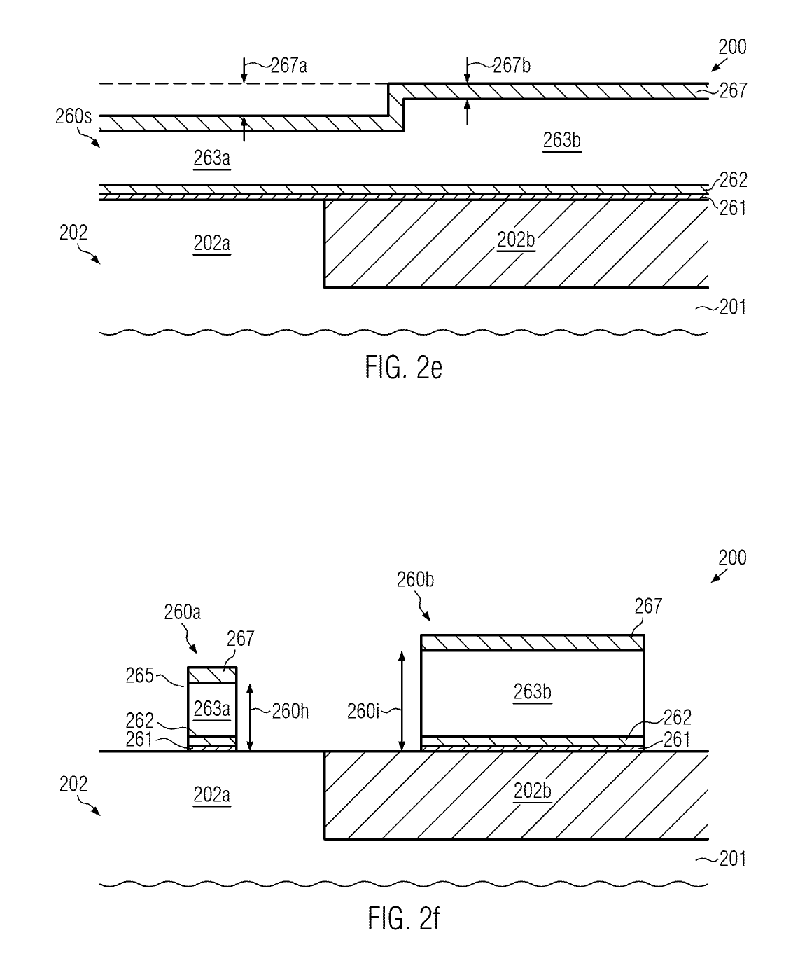

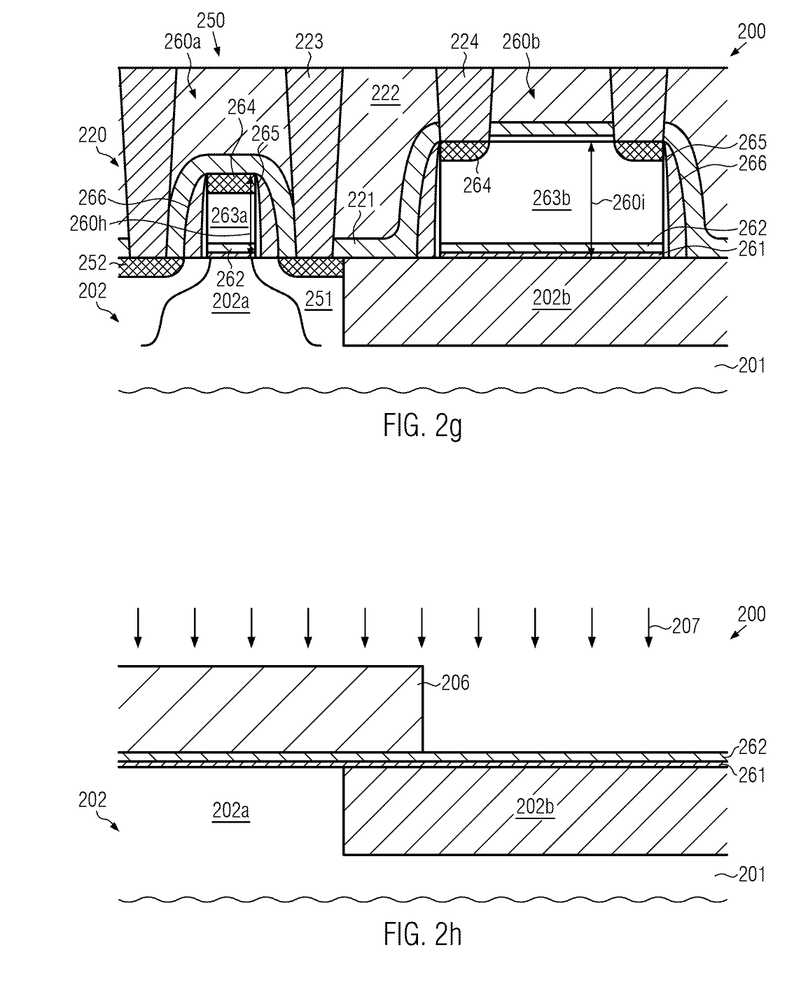

With respect to FIGS. 2a-2h, further illustrative embodiments will now be described in more detail, wherein reference may also be made to FIG. 1, if appropriate.

FIG. 2a schematically illustrates a cross-sectional view of a semiconductor device 200 in an early manufacturing stage. As illustrated, the device 200 comprises a substrate 201 in combination with a semiconductor layer 202, wherein, in one illustrative embodiment, the semiconductor layer 202 and the substrate 201 form a bulk architecture in which the material of the semiconductor layer 202 is in direct contact with a crystalline material of the substrate 201. It should be appreciated, however, that the principles disclosed herein may also be applied to an SOI configuration, in which a buried insulating layer (not shown) may be positioned between the semiconductor layer 202 and the substrate 201. Moreover, a plurality of active regions or semiconductor regions may be provided in the semiconductor layer 202, which are typically laterally separated by appropriate isolation regions (not shown). For convenience, a single semiconductor region or active region 202a is illustrated in FIG. 2a and represents an active region of a transistor to be formed in and above the region 202a so as to comprise a gate electrode structure. Furthermore, an isolation region 202b may be provided in the layer 202 and may be comprised of any appropriate dielectric material, wherein the isolation region 202b represents at least a portion of an area in which a non-transistor device, such as a resistor, an electronic fuse and the like, is to be formed. Furthermore, in this manufacturing stage, a portion of a gate layer stack 260s may be formed above the active region 202a and the isolation region 202b and may have any appropriate configuration. For example, a gate dielectric material 261 and a semiconductor-based electrode material 263 may be provided, wherein the gate dielectric layer 261 may comprise any appropriate dielectric material, which, in some illustrative embodiments, may also comprise or represent a high-k dielectric material having a dielectric constant of 10.0 or higher. For example, hafnium oxide, zirconium oxide, aluminum oxide and the like, possibly in combination with silicon dioxide, silicon oxynitride and the like, may be used as high-k dielectric materials. Furthermore, in some illustrative embodiments when the gate layer stack 260s is to be used to form a high-k metal gate electrode structure, a metal-containing electrode material 262, for instance comprising titanium nitride, tantalum nitride, work function adjusting metal species, such as lanthanum, aluminum and the like, may be provided above the gate dielectric layer 261. Similarly, the semiconductor electrode material 263 may be provided with any appropriate material composition in order to adjust the overall basic characteristics of non-transistor devices and of gate electrode structures still to be formed. For example, the material 263 may be provided in the form of amorphous and/or polycrystalline silicon material, a silicon/germanium mixture and the like. Furthermore, the layer 263 is provided with an initial thickness that is appropriate for forming non-transistor devices according to a specific design and configuration, while the thickness of the layer 263 may be considered inappropriate for forming gate electrode structures for at least transistors of the device 200.

The device 200 as shown in FIG. 2a may be formed on the basis of any appropriate process strategy. That is, the active region 202a and the isolation region 202b may be formed on the basis of process techniques as are also discussed above with reference to the device 100. Thereafter, the gate dielectric layer 261 is formed, for instance, by deposition and/or oxidation and the like, followed by the deposition of the layer 263, wherein, in other embodiments, the one or more metal-containing electrode materials 262 may be provided prior to depositing the layer 263.

It should be appreciated that forming the materials 261 and 262 as a high-k dielectric material in combination with one or more metal-containing electrode materials may require the deposition and patterning of various material layers, possibly in combination with a heat treatment for diffusing work function adjusting metal species into the layer 261 in order to appropriately adjust the electronic characteristics of a metal gate electrode structure for a certain type of transistor. Thereafter, the material 263 is deposited, for instance, by low pressure chemical vapor deposition (CVD) and the like.

FIG. 2b schematically illustrates the device 200 in an advanced manufacturing stage in which an etch mask 204, for instance provided in the form of a resist mask and the like, is formed above the layer stack 260s so as to expose the material 263 at least above the active region 202a. To this end, any well-established lithography techniques may be applied.

FIG. 2c schematically illustrates the semiconductor device 200 when exposed to a reactive etch atmosphere 205, in which material of the exposed portion of the layer 263 is removed in the presence of the etch mask 204. During the process 205, a predetermined degree of material removal, indicated as a recess 263r, is obtained in the exposed portion of the material 263. To this end, well-established plasma assisted etch recipes and/or wet chemical etch chemistries may be applied, wherein the corresponding process parameters are such that the predetermined degree of recessing 263r is obtained. For example, a desired gate height for at least some gate electrode structures may be defined in advance, for instance by referring to measurement results obtained from conventional semiconductor devices, for instance in view of AC performance and the like, and, from any such measurement results, the desired degree of recessing 263r may be determined. For a given etch recipe and respective experiments or from well-known removal rates, the degree of recessing 263r may be efficiently controlled during the etch process 205. It should be appreciated that the mask 204 may be provided so as to expose the material 263 above dedicated active regions in which a corresponding gate height scaling is desired. In other cases, the initial thickness of the layer 263 may be preserved, as is the case above a significant portion of the isolation region 202b. In still other illustrative embodiments (not shown) the process sequence of providing an etch mask and performing an etch process may be repeated so as to provide a different degree of gate height scaling above different active regions. To this end, a further etch mask may be applied, for instance covering the material 263 above the active region 202a, when the recessing 263r is considered appropriate for the gate height scaling of a gate electrode structure to be formed on the active region 202a. In this case, the further etch mask may expose another active region and a further etch process may be performed so as to further increase a previously formed recess, thereby obtaining a more pronounced reduction in gate height of a gate electrode structure to be formed above this active region (not shown), thereby enhancing overall flexibility in providing different gate heights for different types of transistors.

FIG. 2d schematically illustrates the semiconductor device 200 in a manufacturing stage in which the gate layer stack 260s may comprise the semiconductor electrode material with different height levels above various device regions. In the embodiment shown, a semiconductor electrode material 263a having a desired thickness is formed above the active region 202a, while a semiconductor electrode material 263b, which may substantially correspond to the initially provided semiconductor electrode material, may be formed above a significant portion of the isolation region 202b in order to provide a desired electrode height for a non-transistor device to be formed above the isolation region 202b. As discussed above, other semiconductor electrode materials of different height levels may be provided above other device areas if gate electrode structures of different height levels have to be implemented in the semiconductor device 200.

FIG. 2e schematically illustrates the device 200 in a further advanced manufacturing stage. As shown, the gate layer stack 260s may comprise an additional material layer or layer system 267, which may be used as an efficient hard mask material and/or as a dielectric cap layer during the further processing of the device 200. For example, the layer 267 may be provided in the form of a silicon nitride material, possibly in combination with one or more material layers of different composition, such as silicon dioxide layers and the like, wherein, in some illustrative embodiments, the material layer or layer system 267 may be provided with a substantially uniform thickness 267b by using highly conformal deposition recipes, for instance plasma enhanced CVD techniques and the like. In other illustrative embodiments, the layer or layer system 267 may be provided with a different thickness 267a above the material 263a in order to compensate for or at least reduce a step height between the materials 263a and 263b. To this end, the layer or layer system 267 may be applied with an appropriate thickness so as to overfill the previously generated step height between the materials 263a, 263b and thereafter a planarization process, such as a chemical mechanical polishing (CMP) process may be applied so as to remove and planarize the material 267, thereby obtaining the desired thickness 267b above the material 263b, while the increased thickness 267a is obtained above the material 263a. Thereafter, the gate layer stack 260s may be patterned on the basis of sophisticated lithography techniques and etch processes, wherein also appropriate sacrificial planarization materials may be applied so as to compensate for the step height between the materials 263a, 263b if the cap layer 267 may not or may not sufficiently compensate for the step height of the materials 263a, 263b. The patterning of the layer stack 260s may be accomplished on the basis of any appropriate process sequence, for instance using double exposure-double etching process sequences in order to obtain the desired lateral shape and dimensions of gate electrode structures and non-transistor devices.

FIG. 2f schematically illustrates the device 200 in a further advanced manufacturing stage. As shown, a gate electrode structure 260a is formed on the active region 202a and has lateral dimensions as required by the corresponding design rules. For example, a gate length, i.e., in FIG. 2f, the horizontal extension of the material 262 and/or 263a, of 50 nm and significantly less, may be implemented in sophisticated semiconductor devices. Furthermore, in the embodiment shown, the gate electrode structure 260a represents a high-k metal gate electrode structure, in which case the gate dielectric layer 261 comprises a high-k dielectric material followed by at least one metal-containing electrode material in the form of the material 262, as is also discussed above. Moreover, the semiconductor electrode material 263a is provided and defines a preliminary gate height 260h that is substantially determined by the reduced thickness of the material 263a, as discussed above. Moreover, the dielectric layer or layer system 267 may still cover the semiconductor electrode material 263a. Similarly, a non-transistor device 260b is provided above the isolation region 202b and may have, in some illustrative embodiments, a similar configuration compared to the gate electrode structure 260a, except for an increased height 260i, which is substantially determined by the increased thickness of the semiconductor electrode material 263b, as explained above. Also in this case, the cap layer 267 is still formed on the material 263b.

It should be appreciated that, depending on the previous process strategy, the layers 267 of the gate electrode structure 260a on the one hand and of the non-transistor device 260b on the other hand may have a different thickness, as discussed with reference to FIG. 2e. During the further processing, a protective liner or spacer 265 may be formed on sidewalls of the structures 260a, 260b, in particular when the gate electrode structure 260a comprises the materials 261, 262 in the form of a high-k dielectric material and a metal-containing electrode material. To this end, an appropriate liner material may be deposited, for instance, in the form of silicon nitride material having a thickness that is appropriate for obtaining the liners or spacers 265 with a desired width that is compatible with the further processing of the device 200.

As a result, the gate electrode structure 260a and the non-transistor device 260b may be obtained on the basis of a common process sequence, which includes at least the deposition of the material 267 and the patterning of the resulting gate layer stack so as to obtain the desired lateral dimensions for the gate electrode structure 260a and the non-transistor device 260b. Thereafter, the processing may be continued by implementing a strain-inducing semiconductor material (not shown) into the active region of at least some transistor elements, wherein the cap layer 267 may be advantageously used as a deposition mask, while also the liner or spacer 265, or possibly a corresponding layer, may act as a deposition mask for masking active regions and gate electrode structures that may not require the incorporation of a strain-inducing semiconductor material. Next, at any appropriate manufacturing stage, the cap layer 267 may be removed by using any appropriate etch strategy, for instance plasma-based etch recipes, wet chemical etch recipes and the like, and appropriate implantation sequences may be performed so as to adjust the desired dopant concentration in the material 263b and also introduce dopant species for drain and source regions in the active region 202a, which may be accomplished by forming an additional spacer structure and applying appropriate masking regimes, as is also discussed above with reference to the device 100.

FIG. 2h schematically illustrates the semiconductor device 200 in a further advanced manufacturing stage. As illustrated, a transistor 250 comprising the gate electrode structure 260a may be formed in and above the active region 202a and may comprise drain and source regions 251 in combination with metal silicide regions 252. Similarly, a metal silicide 264 may also be formed in the semiconductor electrode material 263a. Furthermore, a sidewall spacer structure 266 may be provided in the gate electrode structure 260a so as to define the lateral profile of the regions 251 and 252. Similarly, the non-transistor device 260b, which is illustrated in the form of a resistor, may comprise metal silicide 264 at least at contact areas within the material 263b, which may be accomplished by blocking the silicidation in other areas of the material 263b, as is also discussed above with reference to the device 100. In other cases, the device 260b may represent an electronic fuse, which may have a substantially continuous metal silicide material (not shown) formed in an upper portion of the material 263b. Consequently, the gate electrode structure 260a may have a final gate height 260h which is substantially defined by the material 263a having incorporated therein the metal silicide 264, while the height 260i of the device 260b is basically determined by the material 263b, possibly in combination with the metal silicide 264, depending on whether this material is formed in contact portions only or extends along the entire material 263b.

Furthermore, the device 220 may comprise a contact level 220 including appropriate dielectric materials, such as a layer 221 and a layer 222, in which may be provided contact elements 223 for connecting to the drain and source areas 251 of the transistor 250. Moreover, contact elements 224 may be provided so as to connect to the gate electrode structure 260a (not shown) and to the device 260b.

The contact level 220 may be formed on the basis of manufacturing techniques as are also described above with reference to the device 100. As a consequence, the device 260b may be formed on the basis of the material 263b defining the appropriate height 260i, while the gate electrode structure 260a may have a dedicated gate height, such as the height 260h, in accordance with overall device requirements, for instance for reducing the parasitic capacitance of the gate electrode structure 260a in view of the contact elements 223.

It should be appreciated that, as discussed previously, other gate electrode structures may be provided with a gate height that differs from the height 260h, which may be accomplished by specifically adapting the initial thickness of the semiconductor electrode material prior to actually patterning the gate electrode structures.

FIG. 2h schematically illustrates the device 200 according to further illustrative embodiments in which metal gate electrode structures are to be provided, wherein, however, the superior conductivity of the metal-containing electrode material formed above the high-k dielectric material is considered inappropriate for the non-transistor device. As shown, in this case, a process 207 may be selectively applied to the material 262 above the isolation region 202b in order to significantly modify at least the characteristics of the initial material 262 or to remove at least the material 262 from above the isolation region 202b. To this end, an appropriate mask 206 such as a resist material and the like may be provided on the basis of any appropriate lithography technique in order to expose a portion of the material 262. In some illustrative embodiments, the process 207 may be applied in the form of an implantation process so as to significantly damage and thus modify the material characteristics of the exposed portion of the layer 262, thereby forming a modified portion having a significantly increased sheet resistivity. Moreover, the process 207 may include a further implantation process so as to introduce a diffusion hindering species that efficiently suppresses a reconfiguration of the initial material characteristics in the modified layer during the further processing of the device 200. It should be appreciated that the process 207 in the form of an implantation process may also be applied in a later manufacturing stage, for instance after forming the semiconductor electrode material or even after patterning the resulting gate electrode structures and the non-transistor devices. In other cases, at least the layer 262 may be removed from above a portion of the isolation region 202b so that the resistance of the non-transistor device is determined by the characteristics of the semiconductor electrode material and any metal silicide formed therein. Consequently, when forming sophisticated high-k metal gate electrode structures in an early manufacturing stage, the electronic characteristics of any non-transistor devices, such as resistors and electronic fuses, may be decoupled from the electronic characteristics of the resulting gate electrode structures not only be applying a desired degree of gate height scaling but also by increasing the sheet resistivity of the metal-containing electrode material by modifying the material characteristics or by removing metal-containing electrode material partially or completely from above a portion of the isolation region 202b in which the non-transistor device is to be formed.

If the process 207 is implemented in the process stage as shown in FIG. 2h, the further processing may be continued as is described above with reference to FIGS. 2a-2g.

In other cases, the process 207 may be applied at any appropriate stage of the overall process flow, as required.

As a result, the present disclosure provides manufacturing techniques and semiconductor devices in which gate height scaling may be applied, in particular for sophisticated high-k metal gate electrode structures, by appropriately reducing the thickness of a semiconductor electrode material in an early manufacturing stage, i.e., prior to actually patterning the gate electrode structures. In this manner, a desired height of non-transistor devices may be implemented while still providing superior AC performance of the gate electrode structures.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a transistor comprising a gate electrode structure having a first height, said gate electrode structure comprising a first high-k gate dielectric material, a metal-containing electrode material formed above said first high-k gate dielectric material and a first semiconductor electrode material formed above said metal-containing electrode material; and
a non-transistor device formed above an isolation region and comprising a second semiconductor electrode material formed above said isolation region, said non-transistor device having a second height that is greater than said first height.

2. The semiconductor device of claim 1, wherein said gate electrode structure further comprises a semiconductor metal compound formed in a portion of said first semiconductor electrode material.

3. The semiconductor device of claim 2, wherein said gate electrode structure comprises an encapsulation liner formed on sidewalls of said first high-k dielectric material and said metal-containing electrode material and wherein said encapsulation liner is comprised of a non-high-k dielectric material.

4. The semiconductor device of claim 1, wherein said non-transistor device comprises a metal semiconductor compound formed in a portion of said second semiconductor electrode material.

5. The semiconductor device of claim 1, wherein said non-transistor device further comprises a second high-k dielectric material formed on said isolation region.

6. The semiconductor device of claim 5, wherein said non-transistor device further comprises a second metal-containing electrode material formed between said second high-k dielectric material and said second semiconductor electrode material.

7. The semiconductor device of claim 6, wherein a sheet resistivity of said second metal-containing electrode material is greater than a sheet resistivity of said metal-containing electrode material of said gate electrode structure.

8. The semiconductor device of claim 1, wherein said non-transistor device is a resistor.

9. The semiconductor device of claim 1, wherein said non-transistor device is an electronic fuse.

10. A method, comprising:
forming a semiconductor electrode material of a gate layer stack above an active region and an isolation region of a semiconductor device;
reducing a thickness of said semiconductor electrode material above said active region and preserving an initial thickness of said semiconductor electrode material above at least a portion of said isolation region; and
forming a gate electrode structure on said active region from said gate layer stack and forming a non-transistor device from said gate layer stack above said isolation region.

11. The method of claim 10, further comprising forming a high-k dielectric material of said gate layer stack prior to forming said semiconductor electrode material.

12. The method of claim 11, further comprising forming at least one metal-containing electrode material above said high-k dielectric material prior to forming said semiconductor electrode material.

13. The semiconductor device of claim 11, further comprising forming a metal semiconductor compound in said semiconductor electrode material of said gate electrode structure and said non-transistor device.

14. The method of claim 12, further comprising increasing a sheet resistivity of said metal-containing electrode material selectively above said at least a portion of said isolation region.

15. The method of claim 14, wherein increasing the sheet resistance of said metal-containing electrode material comprises implanting a heavy species into said metal-containing electrode material.

16. The method of claim 10, further comprising incorporating a dopant species into the semiconductor electrode material above said isolation region so as to adjust a specific resistivity of said semiconductor electrode material of said non-transistor device.

17. The method of claim 10, further comprising forming a dielectric cap layer of said gate layer stack with a first thickness above said active region and with a second thickness above at least said portion of said isolation region, wherein said first thickness is greater than said second thickness.

18. A method of forming a semiconductor device, said method comprising:
forming a semiconductor electrode material above a semiconductor region of a transistor and an isolation region of a non-transistor device;
masking said semiconductor electrode material above said isolation region;
reducing a thickness of said semiconductor material above said semiconductor region by performing an etch process; and
forming said non-transistor device and a gate electrode structure of said transistor from said semiconductor electrode material by performing a common process sequence.

19. The method of claim 18, further comprising forming a high-k dielectric material and a metal-containing electrode material at least above said semiconductor region prior to forming said semiconductor electrode material.

20. The method of claim 18, further comprising forming a metal silicide in said gate electrode structure and said non-transistor device.
